(19) United States
(12) Patent Application Publication
(10) Pub. No.: US 2013/0026380 A1
(43) Pub. Date: Jan. 31, 2013

(54) RADIATION DETECTOR WITH ANGLED SURFACES AND METHOD OF FABRICATION

(71) Applicants: John Eric Tkaczyk, Delanson, NY (US); Steven Robert Hayashi, Niskayuna, NY (US); Haochuan Jiang, Brookfield, WI (US); Wenwu Zhang, Schenectady, NY (US); Kristian William Andreini, Burnt Hills, NY (US); Nitin Garg, Niskayuna, NY (US); Tan Zhang, Niskayuna, NY (US)

(72) Inventors: John Eric Tkaczyk, Delanson, NY (US); Steven Robert Hayashi, Niskayuna, NY (US); Haochuan Jiang, Brookfield, WI (US); Wenwu Zhang, Schenectady, NY (US); Kristian William Andreini, Burnt Hills, NY (US); Nitin Garg, Niskayuna, NY (US); Tan Zhang, Niskayuna, NY (US)

(73) Assignee: General Electric Company, Schenectady, NY (US)

(21) Appl. No.: 13/191,292

(22) Filed: Jul. 26, 2011

(51) Int. Cl. G01T 1/24; H01L 31/18; G01T 1/16

(52) U.S. Cl. 250/370.13; 250/394; 438/73; 257/E31.032

(57) ABSTRACT

Radiations detectors with angled walls and methods of fabrication are provided. One radiation detector module includes a plurality of sensor tiles configured to detect radiation. The plurality of sensor tiles have (i) top and bottom edges defining top and bottom surfaces of the plurality of sensor tiles, (ii) sidewall edges defining sides of the plurality of sensor tiles, and (iii) corners defined by the top and bottom edges and the sidewall edges. The radiation detector module also has at least one beveled surface having an oblique angle, wherein the beveled surface includes beveling of at least one of top or bottom edges, the side wall edges, or the corners.

### STATEMENT REGARDING FEDERALLY SPONSORED RESEARCH AND DEVELOPMENT

This invention was made with government support under U.S. Government Contract Number HSHQDC-08-C-00174 awarded by the Domestic Nuclear Detection Department (DNDO), Department of Homeland Security. The U.S. Government may have certain rights in this invention.

### BACKGROUND

The subject matter disclosed herein relates generally to imaging detectors, and more particularly to solid state radiation detectors.

Detectors for diagnostic imaging systems, for example, detectors for Single Photon Emission Computed Tomography (SPECT) and Computed Tomography (CT) imaging systems are often produced from semiconductor materials, such as Cadmium Zinc Telluride (CdZnTe), often referred to as CZT, Cadmium Telluride (CdTe), Thallium Bromide (TlBr) and Silicon (Si), among others. Semiconductor detectors are characterized by higher energy resolution than detectors fabricated from scintillators. As a result, such materials are also used for security applications that require radiation spectroscopy at room temperature, as well as to perform radio-isotope detection and identification.

These semiconductor detectors used for both imaging and spectroscopy applications typically include arrays of pixelated detector modules. The detector modules are formed from sensor tiles that have sharp angled corners and edges that are vulnerable to fracture because the sensor tiles are unprotected and have no supporting material on one or more sides. Accordingly, these corners and edges have an increased likelihood of chipping. For example, stress, including shock stress, created by mechanical handling of the tiles, such as during assembly and shipping can fracture the sensor tiles. For hand-held or portable spectrometer detectors, mechanical shock can occur due to accidental drop. The stress is mechanically focused and enhanced through the contact with supporting material resulting in more localized strain. In brittle sensor material, this focus effect leads to more crack initiation and propagation at edges and corners as compared to the wide faces.

Additionally, the sharp corners and edges cause electric field enhancement that leads to more current flow and progressive degradation of high voltage operation over time. In operation, a higher bias voltage would be beneficial to electrical charge collection and would improve energy resolution. However, using higher voltages is not possible in conventional detectors because of excessive leakage and the possibility of high voltage breakdown or progressive high voltage tracking, leading eventually to breakdown.

### BRIEF DESCRIPTION

In accordance with various embodiments, a radiation detector module is provided that includes a plurality of sensor tiles configured to detect radiation. The plurality of sensor tiles have (i) top and bottom edges defining top and bottom surfaces of the plurality of sensor tiles, (ii) sidewall edges defining sides of the plurality of sensor tiles, and (iii) corners defined by the top and bottom edges and the sidewall edges. The radiation detector module also has at least one beveled surface having an oblique angle, wherein the beveled surface includes beveling of at least one of top or bottom edges, the side wall edges, or the corners.

In accordance with other embodiments, a medical imaging system is provided that includes a gantry and at least one imaging detector formed from a plurality of detectors modules. The detector modules include a plurality of sensor tiles configured to detect radiation, and having at least one beveled surface defining an oblique angle facet, wherein the beveled surface includes at least one of an edge or a corner of the plurality of sensor tiles.

In accordance with yet other embodiments, a radiation spectrometer system is provided that includes at least one high energy resolution detector formed from a plurality of detectors modules. The detector modules include a plurality of sensor tiles configured to detect radiation, and having at least one beveled surface defining an oblique angle facet, wherein the beveled surface includes at least one of an edge or a corner of the plurality of sensor tiles.

In accordance with still other embodiments, a method for forming a detector module for a radiation detector is provided. The method includes cutting a substrate to form a plurality of sensor tiles and forming at least one beveled surface defining an oblique angle facet on the sensor tiles, wherein the beveled surface includes at least one of an edge or a corner of the plurality of sensor tiles. The method also includes forming a detector module from the sensor tiles having the at least one beveled surface.

### BRIEF DESCRIPTION OF THE DRAWINGS

FIG. 1 is a simplified cross-sectional view of a portion of a pixelated detector.

FIG. 2 is a simplified perspective view of a sensor tile.

FIG. 3 is a perspective view of a detector module formed in accordance with an embodiment.

FIG. 4 is a perspective view of a sensor tile formed in accordance with one embodiment.

FIG. 5 is a top view of a tiled module formed with the sensor tile of FIG. 4.

FIG. 6 is a side view of the tiled module of FIG. 5.

FIG. 7 is a perspective view of a sensor tile formed in accordance with another embodiment.

FIG. 8 is a top view of a tiled module formed with the sensor tile of FIG. 7.

FIG. 9 is a side view of a portion of the tiled module of FIG. 8.

FIG. 10 is a perspective view of a sensor tile formed in accordance with another embodiment.

FIG. 11 is a top view of a tiled module formed with the sensor tile of FIG. 10.

FIG. 12 is a side view of the tiled module of FIG. 11.

FIG. 13 is a perspective view of a sensor tile formed in accordance with another embodiment.

FIG. 14 is a perspective view of a sensor tile formed in accordance with another embodiment.

FIG. 15 is a top perspective view of a tiled module formed with the sensor tile of FIG. 13.

FIG. 16 is a perspective view of a sensor tile formed in accordance with another embodiment and illustrating different shapes.

FIG. 17 is a flowchart of a method for forming detector modules in accordance with various embodiments.

FIG. 18 is a cross-sectional view of a detector package formed in accordance with one embodiment.

FIG. 19 is a perspective view of an interconnect arrangement formed in accordance with one embodiment.

FIG. 20 is a side view of the interconnect arrangement of FIG. 19.

FIG. 21 is a diagrammatic illustration of a detector package assembly process in accordance with various embodiments.

FIG. 22 is a cross-sectional view of a detector package formed in accordance with another embodiment.

FIG. 23 is a perspective view of an exemplary nuclear medicine imaging system constructed in accordance with various embodiments.

FIG. 24 is a block diagram of a nuclear medicine imaging system constructed in accordance with various embodiments.

FIG. 25 is a diagram of a handheld spectrometer device in which various embodiments may be implemented.

### DETAILED DESCRIPTION

The foregoing summary, as well as the following detailed description of certain embodiments will be better understood when read in conjunction with the appended drawings. To the extent that the figures illustrate diagrams of the functional blocks of various embodiments, the functional blocks are not necessarily indicative of the division between hardware circuitry. Thus, for example, one or more of the functional blocks (e.g., processors or memories) may be implemented in a single piece of hardware (e.g., a general purpose signal processor or random access memory, hard disk, or the like) or multiple pieces of hardware. Similarly, the programs may be stand alone programs, may be incorporated as subroutines in an operating system, may be functions in an installed software package, and the like. It should be understood that the various embodiments are not limited to the arrangements and instrumentality shown in the drawings.

As used herein, an element or step recited in the singular and proceeded with the word “a” or “an” should be understood as not excluding plural of said elements or steps, unless such exclusion is explicitly stated. Furthermore, references to “one embodiment” are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

Also as used herein, the phrase “reconstructing an image” is not intended to exclude embodiments in which data representing an image is generated, but a viewable image is not. Therefore, as used herein the term “image” broadly refers to both viewable images and data representing a viewable image. However, many embodiments generate, or are configured to generate, at least one viewable image.

Various embodiments provide an assembly of radiation detector tiles for a radiation detector or detector module where the tiles are fabricated to have substantially oblique angles at one or more edges and/or corners. By practicing various embodiments, the likelihood of chipping is reduced, particularly in brittle sensor materials (e.g. Cadmium Zinc Telluride (CZT)), during handling of the sensor tiles and during processes needed to assemble the sensor tiles into a detector module. Additionally, assembly, disassembly, and field repair may be provided, with a decreased likelihood of fracture of parts in long-term use. Lower electric field enhancement at the surface of oblique-angled edges and/or corners can also allow for higher voltage bias without current leakage or surface breakdown. Additionally, the oblique angled edges and/or corners can result in improved consistency of the overall response of the detector, thus, increasing the energy resolution at the edge of the detector due to more consistent response.

Various other embodiments also provide packaging for multiple sensor parts (e.g., CZT or Thallium Bromide (TlBr) sensor tiles) bonded together into a sensor package. By practicing various other embodiments, a detector module is housed in a structure that can absorb shock, for example, associated with dropping the detector module.

Accordingly, various embodiments may provide pixelated solid-state (e.g., semiconductor) detectors and packaging for such detectors. Different configurations and arrangements of pixelated detectors, for example, pixelated gamma camera tiles having different angled edges and/or corners are provided. Detectors formed in accordance with various embodiments may be used in different types of radiation detection imaging systems, for example, Single Photon Emission Computed Tomography (SPECT), Positron Emission Tomography (PET) and/or x-ray or Computed Tomography (CT) imaging scanners, among others. Detectors formed in accordance with various embodiments also may be used in different types of radiation spectrometer systems including radio-isotope identification devices (RIIDs).

It should be noted that although the various embodiments are described in connection with medical imaging systems and security application spectrometers having particular components, including specific configurations of detectors, the various embodiments are not limited to medical imaging systems or to the specific detectors described herein. Accordingly, the various embodiments may be implemented in connection with any type of diagnostic imaging system, for example, medical diagnostic imaging system (e.g., CT or x-ray system), non-destructive testing system, security monitoring system (e.g., air baggage or airport security imaging system), a hand-held RIID, etc. Additionally, the configurations and arrangements may be modified such that in various embodiments the angle of the edges and/or corners may be provided as desired or needed.

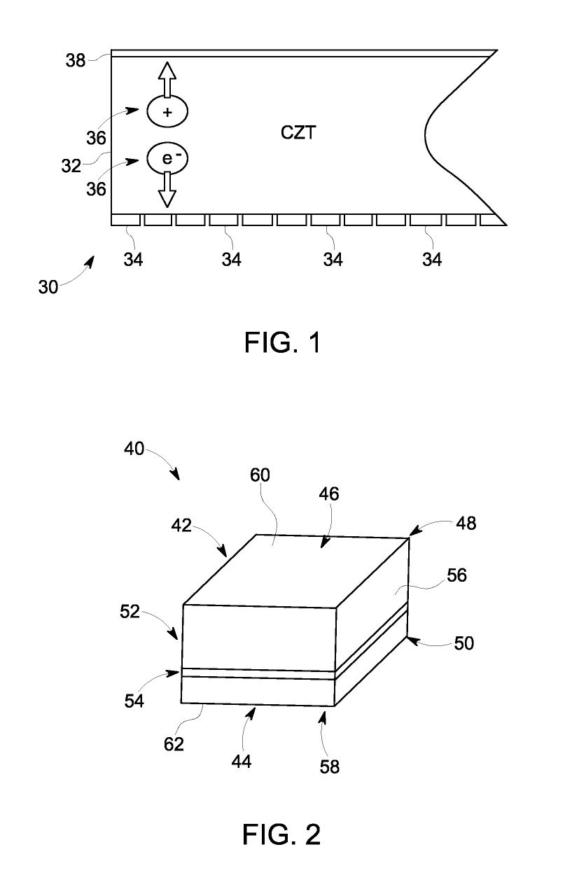

In particular, FIG. 1 is a simplified cross-sectional elevation view of a pixelated detector 30 formed in accordance with various embodiments. The pixelated detector 30 includes a substrate 32 formed from a radiation responsive semiconductor material, for example, CZT crystals. A pixelated structure having a plurality of pixels is defined by photolithography or by cutting or dicing of the contact metal on one surface or side of the substrate to form a plurality of pixel electrodes, identified as anodes 34. As described in more detail herein, a shape and configuration of sensor tiles 40 (shown in FIG. 2), in particular, the angle of the edges and/or corners of the sensor tiles 40 are provided to form angled portions and such tiles 40 may be combined to form the pixelated detector 30 (which in various embodiments is a detector module). In operation, a charge in the pixel electrodes, namely the anodes 34 is induced from an electron-hole pair 36 generated from a detected photon that is absorbed in the substrate 32.

The pixelated detector 30 also includes a cathode 38 on an opposite surface or side of the substrate 32 from the anodes 34 and which may be formed from a single cathode electrode. It should be noted that the anodes 34 generally define the pixels. It also should be noted that one or more collimators may be provided in front of a radiation detecting surface defined by the cathode 38.

FIG. 2 illustrates a sensor tile 40, which may be, for example, a CZT detector tile that may include one or more angled edges and/or corners as described in more detail herein. The sensor tile 40 in various embodiments is formed from any suitable radiation detecting material, which may a semiconductor material or a non-semiconductor material. The sensor tile 40 may be formed from a substrate shaped and sized to accommodate a particular detector or module. For example, in one embodiment, the sensor tile 40 is about 20 mm by 20 mm and has a thickness of between about 5 mm and about 10 mm. Additionally, although the sensor tile 40 is illustrated as generally square, the sensor tile 40 may take different shapes, such as any rectangular shape (or other shape).

The illustrated sensor tile 40 includes a total of six faces, eight corners and twelve edges as described below. One or more of the edges and/or corners of the sensor tiles 40 are angled or curved as described herein. The sensor tile 40 generally includes four top electrode edges 42 and four bottom electrode edges 44. The four top electrode edges 42 define a detection surface 46 therebetween, for example, to detect x-rays or gamma rays, thereby defining a cathode of the sensor tile 40. The sensor tile 40 also generally includes four top corners 48 and four bottom corners 50 that define an anode 58 of the sensor tile 40. Additionally, the sensor tile 40 also generally includes four sidewall edges 52 that define four walls, shown as the four sides 56. The sensor tile 40 may also optionally include a guard band 54 (which may be an electrode that extends around the sides 56 of the sensor tile 40). The guard band 54 may be electrically biased or unbiased, and is formed from any suitable metal. An optional guard ring (not shown) also may be provided, such as on the anode side of the sensor tile 40.

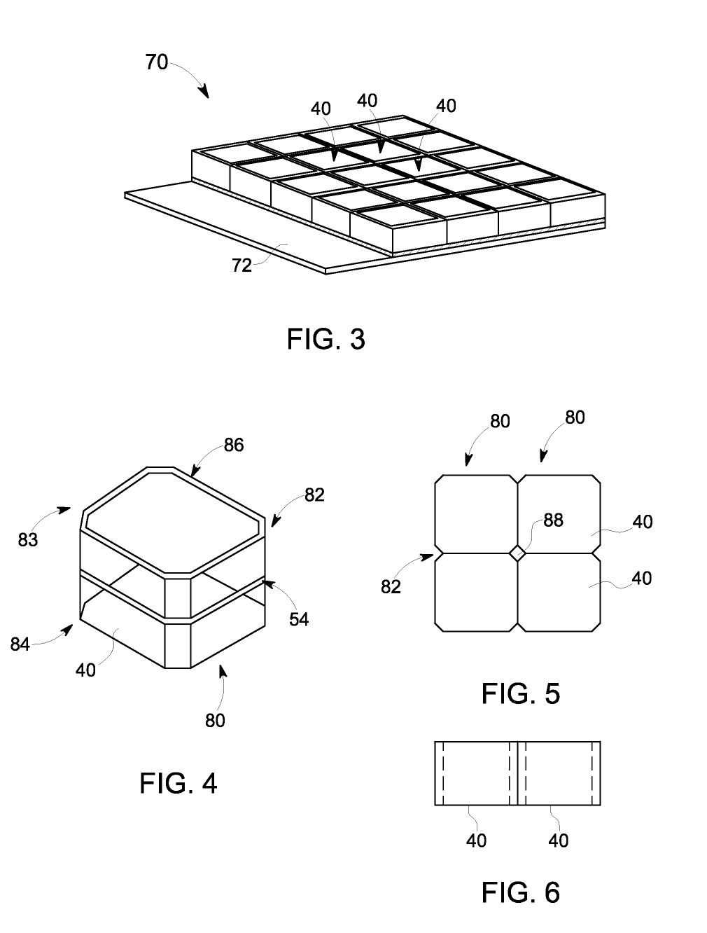

The sensor tile 40 may be combined to form a detector or module 70 as shown in FIG. 3. For example, a rectangular gamma camera module 70 that includes a plurality, for example, twenty sensor tiles 40 is arranged to form a rectangular array of five rows of four sensor tiles 40. The sensor tiles 40 are shown mounted on a motherboard 72 or other processing and/or communication circuitry. It should be noted that modules 70 having larger or smaller arrays of sensor tiles 40 may be provided. It should also be noted that the energy of a photon detected by the sensor tiles 40 is generally determined from an estimate of the total number of electron-hole pairs produced in a crystal forming the sensor tiles 40 when the photon interacts with the material of the crystal. This count is generally determined from the number of electrons produced in the ionizing event, which is estimated from the charge collected on the anode of the sensor tiles 40.

Various embodiments of sensor tiles 40 will now be described. The sensor tiles 40 generally have one or more edges or corners that are angled, slanted, curved or otherwise shaped differently than a generally squared, or perpendicular edge. For example, in various embodiments, one or more of the edges or corners of the sensor tiles 40 have oblique surfaces or facets. It should be noted that an oblique surface, as used herein, generally refers to a surface that is neither perpendicular nor parallel to the surfaces it intersects. The oblique surface forms an interior angle which is more than 90 degrees and less than 180 degrees to the surfaces it intersects. Thus, the oblique surface in various embodiments is a generally inclined surface forming no right angles and/or is not perpendicular to a base.

The one or more edges or corners of the sensor tiles 40 may have, for example, a continuous slope or may be formed in a stepwise configuration. However, variations and modifications are contemplated, such as a radiused edge and/or corner instead of facets. In some embodiments, a chamfered edge with some rounding at the two edges created by the chamfer may be provided. It should be noted that like numerals represent like parts throughout the Figures.

For example, FIGS. 4 through 6 illustrate a faceted sidewall edge arrangement 80 for the sensor tile 40. In particular, four side wall edge facets 82 are provided extending between a top 83 and a bottom 84, namely between the top and bottom corners 48 and 50. The side wall edge facets 82 generally extend at an oblique angle from one top electrode edge 42 to an adjacent top electrode edge 42 and from one bottom electrode edge 44 to an adjacent bottom electrode edge 44. Thus, instead of having generally ninety degree or squared corners 48 and 50, the corners 48 and 50 are angled along the sidewall edges 52. For example, in one embodiment, the interior oblique angle between the edge facets 82 and the sidewall surfaces, namely the sides 56 is 135 degrees.

The side wall edge facets 82 may be formed from any suitable process. For example, the side wall edge facets 82 may be formed from polishing and or abrading the sidewall edges 52 or cutting the sidewall edges 52 (e.g., using laser cutting or water jet cutting).

It should be noted that in addition to the guard band 54, a guard ring 86 may be provided (shown in FIG. 4 on the cathode side of the sensor tile of the faceted sidewall edge arrangement 80) in any suitable manner known in the art. The guard ring 86 also may be provided on the anode side of the sensor tile of the faceted sidewall edge arrangement 80. For example, the guard band 54 and/or the guard ring 86 may be formed by wrapping a metalized polymer sheet around the formed sensor tile 40. As another example, the guard band 54 and/or the guard ring 86 may be formed using a lithography process with contacts. For example, photolithography of the anode side can be used to form the guard ring at the same time as forming the anode pixel contacts defining the anodes 34.

Thus, as can be seen in FIG. 5, a tiled detector or detector module (e.g. the module 70 shown in FIG. 3) may be formed that has a gap 88 between four adjacent corners 48 and 50 of the sensor tiles 40. The gaps 88 generally define a passage from the top 83 to the bottom 84 of the module, which may used, for example, to receive therethrough high voltage wiring or for sidewall guard-band wiring. It should be noted that in some embodiments, the edge facet dimensions of the side wall edge facets 82 are about 0.1 mm to 0.5 mm in width. However, larger or smaller facets may be provided.

It also should be noted that for isotropic materials, and in one embodiment, an oblique angle of 135 degrees is the bevel angle for the side wall edge facets 82. However, the angle degree may be changed, for example, as desired or needed, or based on the type of material used to form the sensor tile 40, such as for single crystal like CZT.

It also further should be noted that variations are contemplated to the faceted sidewall edge arrangement 80. For example, a rounded edge, such as with a radius dimension of about 100 μm (micron) may be formed, such as, using a soft abrasive process.

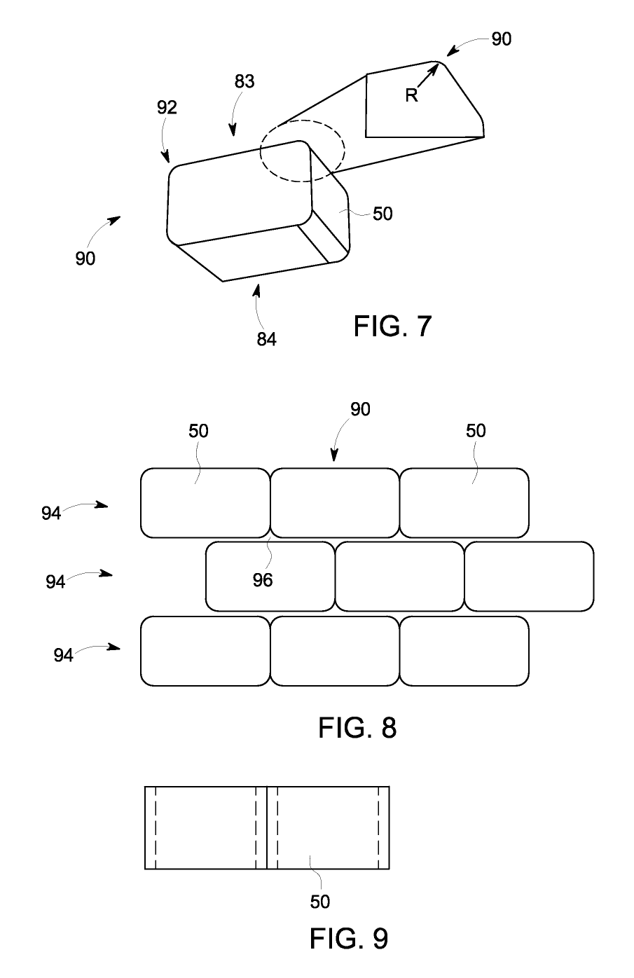

In another embodiment, as shown in FIGS. 7 through 9, a radiused sidewall edge arrangement 90 for the sensor tile 40 may be provided. In particular, four radiused side wall edges 92 are provided extending between the top 83 and the bottom 84, namely between the top and bottom corners 48 and 50. The radiused side wall edges 92 are generally convex curved corners having a curve of radius R. Thus, the radiused side wall 92 extend in a generally continuous curve from one top electrode edge 42 to an adjacent top electrode edge 42 and from one bottom electrode edge 44 to an adjacent bottom electrode edge 44. Thus, the sidewall edges 52 are provided with a radius instead of a facet as shown in FIGS. 4 through 6.

In one embodiment, the sensor tiles 40 have a generally rectangular cross-section and a tiled detector or detector module (e.g. the module 70 shown in FIG. 3) formed from the radiused sidewall edge arrangement 90 has detector rows 94 that are offset from adjacent rows 94 such that a gap 96 is formed between the corners 48 and 50 of two sensor tiles 40 and a side defined by one top and bottom edge 42 and 44 of an adjacent sensor tile 40. However, it should be noted that a non-offset arrangement similar to the arrangement shown in FIG. 5 may be provided (having aligned sensor tiles 40), as well as providing different degrees of offsetting.

The radiused side wall edges 92 may be formed from any suitable process. For example, the radiused side wall edges 92 may be formed from polishing the sidewall edges 52 or cutting the sidewall edges 52 (e.g., using laser cutting, disk cutting, water jet cutting). In some embodiments, hard tooling creates the chamfer and the rounding.

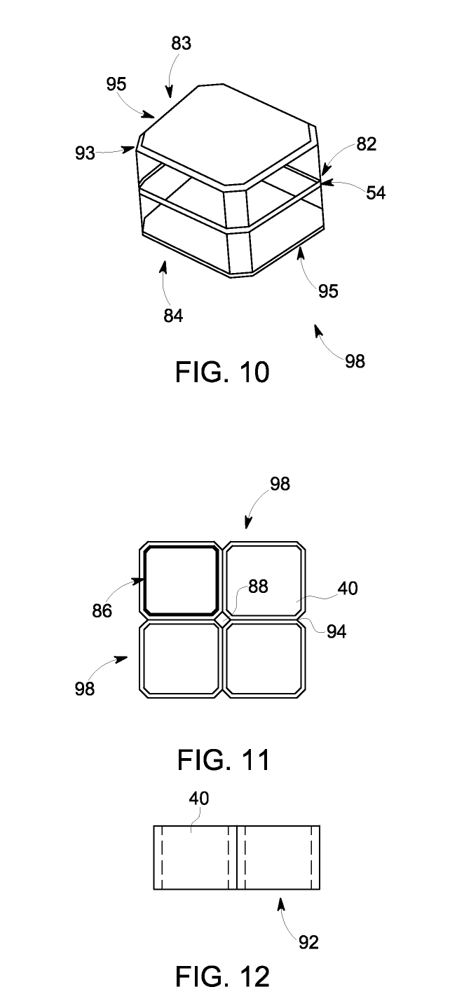

In yet another embodiment, as shown in FIGS. 10 through 12, in addition to the four side wall edge facets 82, corner facets 93 and/or electrode edge facets 95 may be provided to form a sensor tile 40 having a multi-faceted edge arrangement 98. In this embodiment, at each of the corners 48 and 50, and/or along each of the top and bottom electrode edges 42 and 44, additional faceting is provided, namely facets that extend at oblique angles downward from the top 83 and/or upward from the bottom 84. Thus, instead of having generally ninety degree or squared corners 48 and 50, and/or along each of the top and bottom electrode edges 42 and 44, additional facets are provided such that oblique (e.g., greater than 90 degree) angles exist where facet planes meet, such that the entire top 83 is not planar. It should be note that any of the facets may have a single step (e.g., an inclined wall) or multiple steps (similar to an emerald cut).

The corner facets 93 and/or electrode edge facets 95 may be formed from any suitable process. For example, the corner facets 93 and/or electrode edge facets 95 may be formed using laser machining when cutting the sensor tiles 40, such as by defining a scanning protocol combined with changing the laser-part angle in discrete steps. Alternately, a pointed wheel can be used. It should be noted that in some embodiments, the chamfer is provided first by grooving the surface with a “V” tool (e.g., a wheel for OD saw) and then cutting therethrough. It also should be noted that any of the beveled edges may be formed through lapping and polishing, such as using a suitable device.

Beveled edges also may be created one at a time or a plurality can be created at once depending on the application creating the bevel. However, it should be noted that the beveling can be made in different ways, but with respect to creating the beveled edge with a linear saw or blade, the substrate can be fixtured to create the desired bevel or the blade, laser, or fluid stream can be angled to create the desired bevel. Also, when saw blades are used, the blades may be prepared or dressed prior to cutting to ensure that the blade has uniform dimensions as the blade cuts into the substrate material.

Accordingly, in some embodiments, the beveled edge will form the edge after a rectangular, square or any six sided shape has been cut from the substrate (e.g., wafer). The beveling may be performed directly on the wafer. It should be noted that beveling the edges may create component parts with more than six sides and up to, for example, twenty six sides.

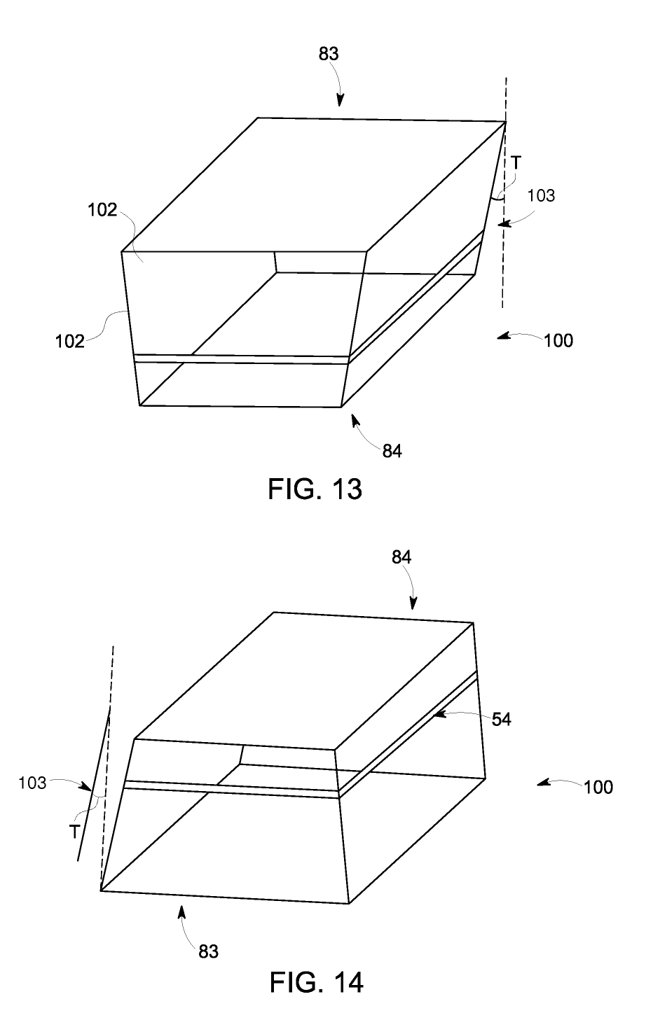

In still other embodiments, an angled sidewall arrangement 100 for the sensor tile 40 is provided as illustrated in FIG. 13 through 15. In particular, four angled side walls 102 are provided extending between the top 83 and the bottom 84, namely between the top and bottom electrode edges 42 and 44. Thus, instead of having walls that are generally perpendicular between the top 83 and the bottom 84, the four angled side walls 102 (which may be tapered walls) are provided at angles (T) 103. The tapering of the angled side walls 102 is shown as a constant slope, but may also be provided in a stepwise arrangement. Additionally, the tapering may be from the top 83 to the bottom 84 as shown in FIG. 13, or vice versa, as shown in FIG. 14. Each of the angled side walls 102 or pairs of the angled side walls 102 may have the same or different taper angle.

The angled side walls 102 may be formed from any suitable process. For example, in some embodiments, the angled side walls 102 may be formed from a laser jet or a water jet that performs the cutting. The degree of the sidewall angles can be controlled by the angle of the laser or the water angle. It should be noted that additional tapering, such as tapering of any of the edges or corners may be provided as described in more detail herein.

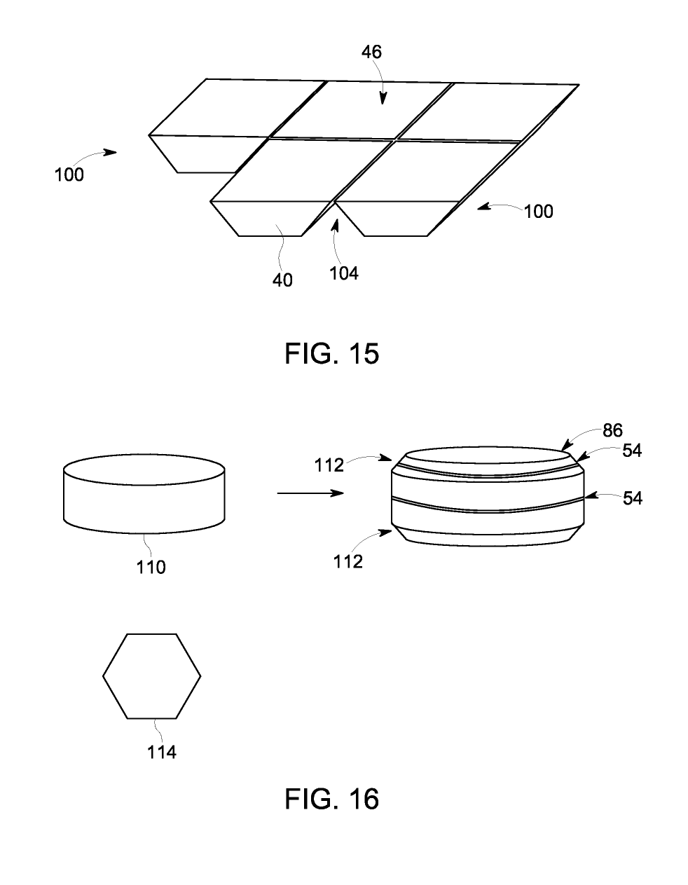

Thus, as can be seen in FIG. 15, a tiled detector or detector module (e.g. the module 70 shown in FIG. 3) may be formed with gaps 104, which are wedge shaped gaps, provided between the sensor tiles 40. The gaps 104 may provide additional space for the sidewall guard band 54 (e.g., the sidewall guard band electrode). It should be noted that the module formed from the sensor tiles 40 having the angled sidewall arrangement 100 may be oriented in the same direction as illustrated in FIG. 15, or different ones of the sensor tiles 40, for example, adjacent sensor tiles 40 may have oppositely facing tapers, such as shown in FIGS. 13 and 14, respectively. Thus, in this embodiment, no gap 104 exists.

Additionally, different shapes of sensor tiles may be provided. For example, a sensor tile 110 as shown in FIG. 16 may be provided having a generally circular cross-section defining a cylindrical body. As another example, a sensor tile 114 may be provided having a hexagonal shape. However, other shapes are contemplated, for example, ovals. As illustrated, beveled top and bottom edges 112 may be provided, which may be formed as described in more detail herein. Additionally, one or more guard bands 54 or guard rings 86 may be provided. FIG. 16 illustrates different possible positions for the one or more guard bands 54 or guard rings 86, such as on the edge facet. Accordingly, the beveled top and bottom edges 112 may be formed wide enough to receive a metalized ring.

The beveling of round, oval or cylindrical embodiments may be provided using any suitable process. For example, the beveling may be performed by direct machining or polishing.

It should be noted that in the various embodiments, a final processing step may be performed wherein the facets and/or bevels are coated with a slick, hard coat, hydrophobic material. The coating generally encapsulates the surfaces of the facets and/or bevels and prevents the surfaces from holding dirt or attracting moisture and to spread the load from handling stress over a wider area.

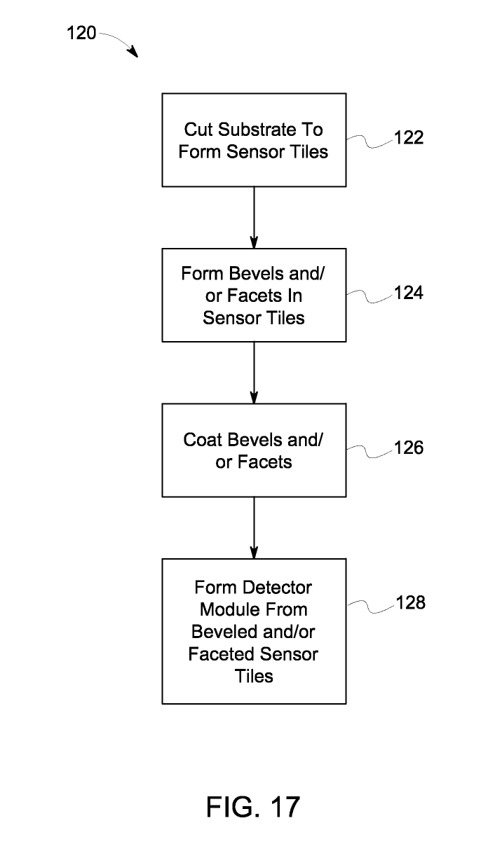

In accordance with various embodiments, a method 120 as shown in FIG. 17 is provided for forming detector modules. The method includes at 122 cutting a substrate (e.g., a semiconductor substrate) into a plurality of sensor tiles having a determined cross-sectional shape, for example, square. During this process, or thereafter, one or more bevels and/or facets are formed in the sensor tiles at 124. In various embodiments, the forming of the sensor tiles with beveled and/or faceted edges, corners or walls (as described in more detail herein) may be provided as part of the machining process that frees the substrate from the starting wafer or can be applied after forming the shaped sensor tile. For example, laser cutting can cut through the wafer and leave a taper on the sidewall. As another example, the tile can be placed in a fixture that defines fixed angles and lapping can be applied to the edges and corners to form the facets. In some embodiments, a combination of lapping with motion can affect a radius at edges and corners. Also, additional facets may be formed on the sensor tile during the cutting process or by subsequent cutting or lapping operations to thereby create the oblique angles at the edges and corners. Alternately, the tiles may have corners and edges machined with a radius instead of facets. Also, a combination of facets and radiused processing may be used in some embodiments. In addition to facets and a radius, as described in more detail herein, the tiles can be cut to have a draft-taper.

Thereafter, the bevels and/or facets are optionally coated at 126. Finally, a plurality of beveled and/or faceted sensor tiles is combined to form a detector module at 128. For example, the sensor tiles may be mounted to any suitable support structure, which may include electrical connections for connecting to the sensor tiles.

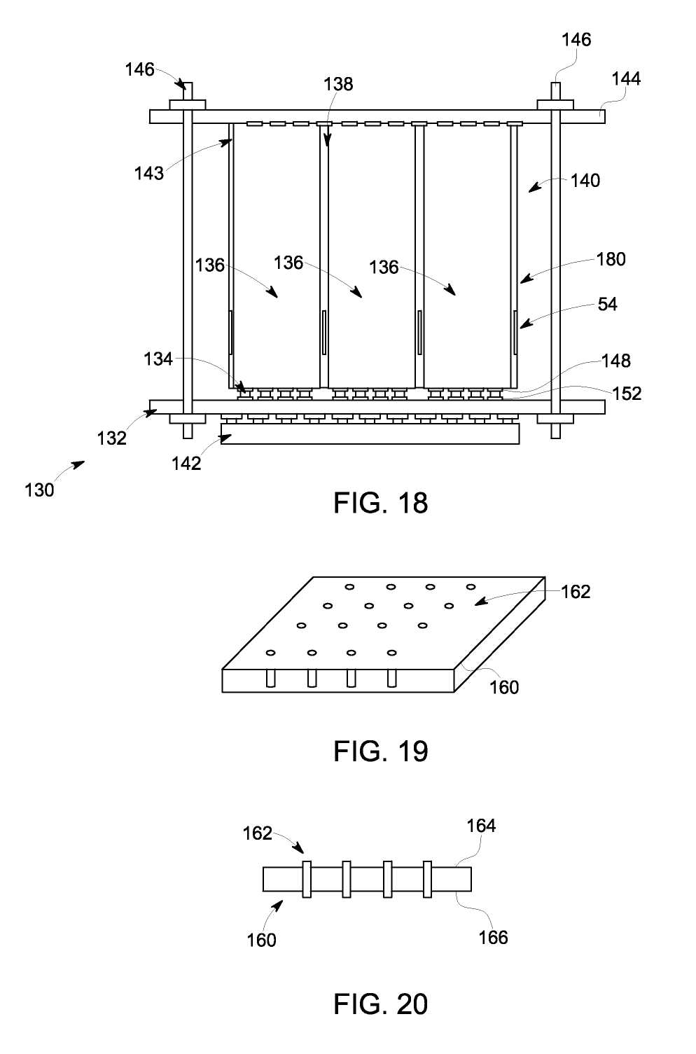

In accordance with various embodiments, a de-mountable detector packaging, such as for CZT detector modules, is provided. The detector modules may be formed from sensor tiles having bevels and/or facets as described herein, or may have be formed from sensor tiles having generally squared edges and corners. In particular, in one embodiment, a detector package 130 as illustrated in FIG. 18 is provided. The detector package 130 includes a substrate 132, which in various embodiments is a ceramic substrate, such as a multi-layer ceramic substrate. However, other substrate materials may be used, such as an alumina substrate, organic circuit boards or a reinforced epoxy laminate sheet (e.g., FR-4), among others.

An interconnect arrangement illustrated as a plurality of interconnects 134 are provided to connect the substrate 132 with a plurality of sensor tiles 136, which in one embodiment are CZT sensor tiles. In some embodiments, the sensor tiles 136 are formed similar to the sensor tiles 40 having bevels and/or facets. Additionally, the sensor tiles 136 are coupled together with a bonding material 138, which may be, for example, glue, epoxy or other adhesive. The interconnects 134 may include metal, solder (e.g., solder bumps or balls) or conductive adhesive (e.g., epoxy plus a filler, such as nickel or graphite), among other materials, that connect anodes 148 (illustrated as anode pads) to pads 152 on the substrate 132.

Thus, various interfaces are generally provided between a sensor pack 140 (formed from the coupled sensor tiles 136) and the substrate 132 that are subject to stress, for example, during assembly, during temperature changes and due to shock events. For example, an interface is provided by the electrical interconnect using the interconnects 134 that couples the sensor tiles 136 to the substrate 132. Another interface is provided by the sidewall bonding.

A coefficient of thermal expansion (CTE) mis-match induced stress can deteriorate the interfaces and degrade the detector performance. In one embodiment, the CTE of each material in the assembly is in the range of:

CZT=5.8 ppm/K;

Ceramic=6 ppm/K (selected to match the CTE of CZT);

Interconnect material=16-100 ppm/K; and

Sidewall bonding material=30-200 ppm/K.

With respect more particularly to the interfaces, and in one embodiment, the sensor tiles 136 are mechanically bonded together with the bonding material 138, which in various embodiments is a high elastic modulus adhesive. In one embodiment, the bonding is electrically inactive, but can optionally include metallic elements to shape the internal electric field within the sensor tiles 136.

The sensor pack 140 is connected through the interconnects to the substrate 132 at the anode side that provides charge signal routing to a processor, which in this embodiment, is an Application-Specific Integrated Circuit (ASIC) 142, providing suitable processing components, such as known in the art. The anode side interconnect is shown in more detail in FIGS. 19 and 20. This interconnect can reduce or minimize the stress applied to the sensor pack 140.

The sensor pack 140 also has a cathode interconnect 143, which provides a high voltage connection in this embodiment. The cathode interconnect 143 can be formed from a flexible material with metallizations that route high voltage to each of the sensor tiles 136. It should be noted that an electrically conductive adhesive may be used to attach the metallizations to the cathode contact of the sensor tiles 136.

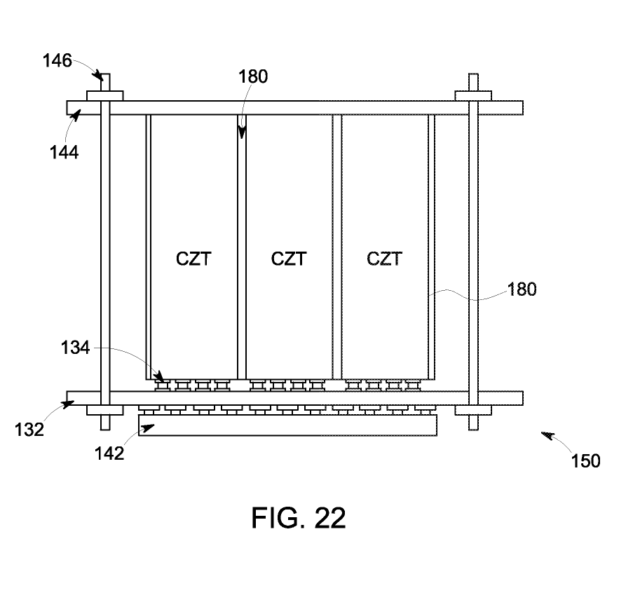

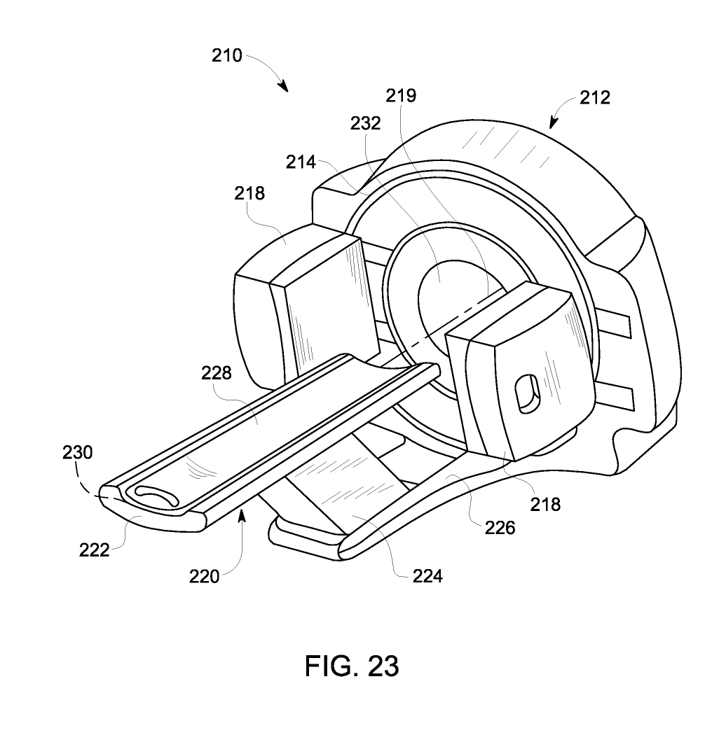

A plate 144, which in this embodiment is a rigid plate, is attached at the cathode side of the sensor tiles 136, and with the anode side secured to the substrate 132 forms a rigid housing that resists or prevents deformation under shock. It should be noted that a foam layer 150 (e.g., foam injected molding) as shown in FIG. 22 may be provided over the entire assembly (shown in FIG. 22 only over a portion of the assembly) to resist shock by deformation of the foam when shock occurs. Thus, in various embodiments, the foam layer 150 deforms, but not the rigid housing and less stress is applied to the sensor tiles 136.

The rigid housing also includes control pins 146 that are adjustable (e.g., rotatably adjustable) to apply pressure to the substrate 132 and the plate 144 to maintain the rigid housing. It should be noted that other mechanical structures, such as plates, beams and different enclosures may be used to provide support and rigidity.

Thus, in various embodiments a layer of an anisotropic conductive material along with the interconnects 134 are maintained under a compression force. When releasing the compression applied by the control pins 146, the sensor tiles 136 can be removed. An example of the anisotropic conductive material arrangement is illustrated in FIGS. 19 and 20. In this embodiment, a base 160 is provided, such as formed from a low elastic modulus material or other anisotropic conductive material. A plurality of metalized interconnects, which in this embodiment are metal vias 162, extend through the base 160 and beyond the top and bottom surfaces 164 and 166 of the base 160. Thus, the metal vias 162 are embedded within the base 160. Accordingly, metalized interconnects are accessible on the top and bottom surfaces 164 and 166. It should be noted that the metal vias 162 may be formed from any suitable conductive material, for example, copper. In one embodiment, the metal vias 162 are copper pillars or posts within a closed cell foam material, such as a compliant base material.

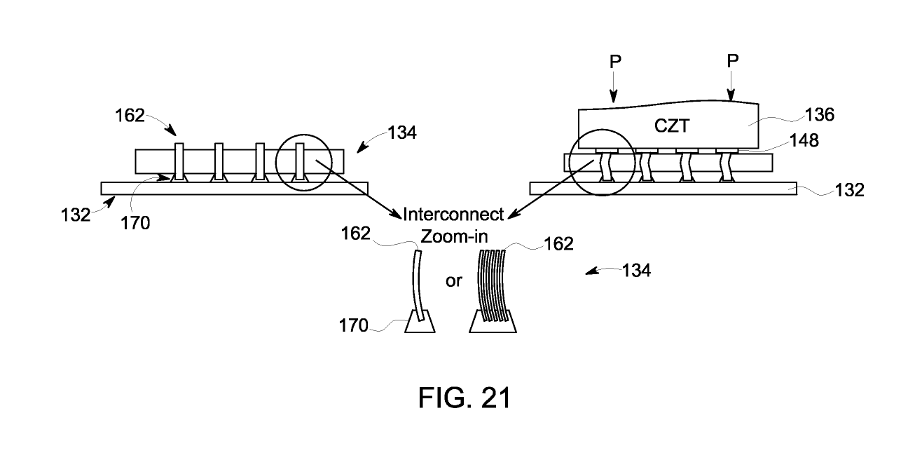

FIG. 21 illustrates the coupling of the sensor tiles 136 to the substrate 132 using the interconnects 134 (e.g., a detector assembly process). For example, a CZT to ceramic substrate assembly and re-work process may be provided as follows:

1. Attach the base 160, namely the layer of anisotropic conductive material on the substrate 132 (e.g., the ceramic substrate) with a connector attach material 170, for example, silver epoxy, solder or other conductive epoxy.

2. Align the anodes 148 to the anisotropic conductive material, then apply pressure, illustrated by the P arrows, and secure the control pins 146. As can be seen, the metal vias 162 bend or deform (e.g., bend slightly) under compression, and the polymer base material of the base 160 provides the pressure for the connection arrangement for good contact. It should be noted that the metal vias 162 may be formed from a single rod or strand, or multiple rods or strands.

3. If one of the sensor tiles 136 is not functioning, the individual sensor tile 136 can be replaced by unloading the control pins 146 and replacing the sensor tile 136, thereby providing a re-workable assembly process.

It should be noted other interconnect arrangements may be provided using, for example, metal-covered balls, high-standoff deposits of metal-filled epoxy, stud-bumps, plated bumps, or solder balls, among others. In various embodiments, the conductive adhesive has a high standoff to accommodate CTE mismatch.

It should be noted that surface protection may be provided. For example, the sensor tiles 136 may be protected from contaminants as illustrated in FIG. 22. For example, for CZT tiles, the tiles are oxidized using wet chemicals (e.g., 0.01-30% hydrogen peroxide, a solution of sodium hypochlorite) or by dry oxidation (e.g., any oxidizing gas including oxygen gas or water vapor present in air at room temperature up to about 150 degrees Celsius). Thus, a surface passivation and encapsulation layer 180 may be provided.

The CZT tiles are then bonded together, such as with thermoplastic adhesives before assembly, and treated as a monolithic detector during assembly. Alternately, a post assembly may be provided having a chemical vapor deposited polymer coating to protect the CZT tile surface from contamination and provide low surface leakage.

Thus, the detector package 130 may reduce the force applied to the sensor material by spreading the momentum transferred during a shock event over a longer time scale associated with the deformation of the foam encapsulation. Additionally, the interconnect construction allows for CTE mismatch between the substrate and sensor material, while reducing the likelihood of damage to the sensor material.

Accordingly, various embodiments provide detector modules with oblique angle tiles. Additionally, a de-mountable shock resistant detector packaging is also provided. The detector in various embodiments is thereby robust to degradation and fracture.

The various embodiments may be provided as part of different types of imaging systems, for example, Nuclear Medicine (NM) imaging system such as PET imaging systems or SPECT imaging systems, x-ray imaging systems and CT imaging systems, among others. For example, FIG. 23 is a perspective view of an exemplary embodiment of a medical imaging system 210 constructed in accordance with various embodiments, which in this embodiment is a SPECT imaging system. The system 210 includes an integrated gantry 212 that further includes a rotor 214 oriented about a gantry central bore 232. The rotor 214 is configured to support one or more nuclear medicine (NM) pixelated cameras 218 (two cameras 218 are shown), such as, but not limited to gamma cameras, SPECT detectors, multi-layer pixelated cameras (e.g., Compton camera) and/or PET detectors formed using the detector modules described herein. It should be noted that when the medical imaging system 210 includes a CT camera or an x-ray camera, the medical imaging system 210 also includes an x-ray tube (not shown) for emitting x-ray radiation towards the detectors. In various embodiments, the cameras 218 are formed from pixelated detectors as described in more detail herein. The rotors 214 are further configured to rotate axially about an examination axis 219.

A patient table 220 may include a bed 222 slidingly coupled to a bed support system 224, which may be coupled directly to a floor or may be coupled to the gantry 212 through a base 226 coupled to the gantry 212. The bed 222 may include a stretcher 228 slidingly coupled to an upper surface 230 of the bed 222. The patient table 220 is configured to facilitate ingress and egress of a patient (not shown) into an examination position that is substantially aligned with examination axis 219. During an imaging scan, the patient table 220 may be controlled to move the bed 222 and/or stretcher 228 axially into and out of a bore 232. The operation and control of the imaging system 210 may be performed in any manner known in the art. It should be noted that the various embodiments may be implemented in connection with imaging systems that include rotating gantries or stationary gantries.

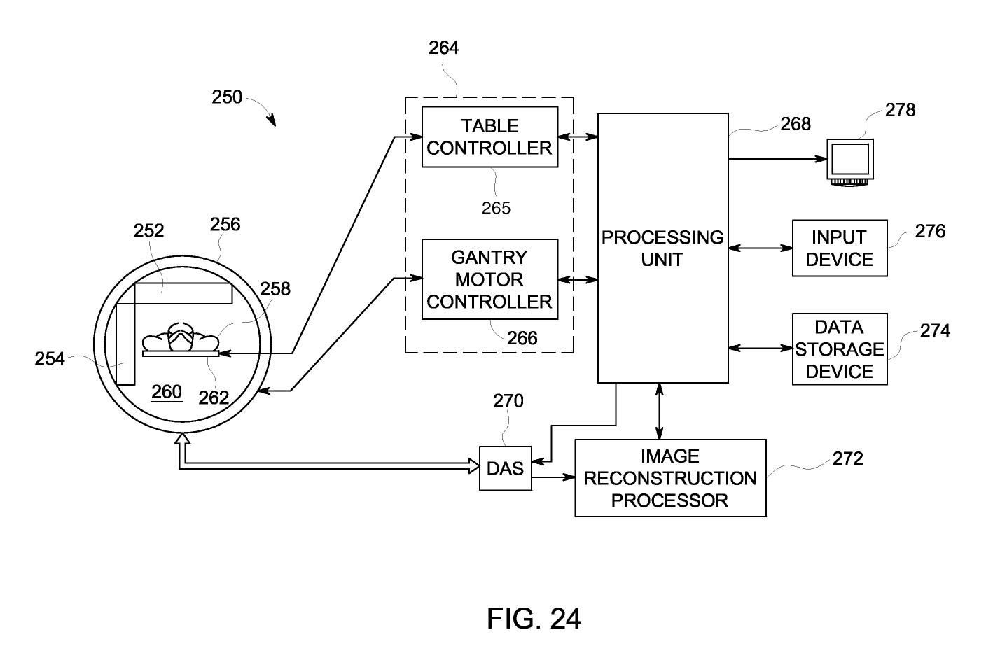

FIG. 24 is a block diagram illustrating an imaging system 250 that has a plurality of imaging detectors provided in accordance with various embodiments mounted on a gantry. It should be noted that the imaging system may also be a multi-modality imaging system, such as an NM/CT imaging system. The imaging system 250, illustrated as a SPECT imaging system, generally includes a plurality of pixelated imaging detectors 252 and 254 (two are illustrated) mounted on a gantry 256. The imaging detectors 252 and 254 may be formed from the detector modules described herein. It should be noted that additional imaging detectors may be provided. The imaging detectors 252 and 254 are located at multiple positions (e.g., in an L-mode configuration) with respect to a patient 258 in a bore 260 of the gantry 256. The patient 258 is supported on a patient table 262 such that radiation or imaging data specific to a structure of interest (e.g., the heart) within the patient 258 may be acquired. It should be noted that although the imaging detectors 252 and 254 are configured for movable operation along (or about) the gantry 256, in some imaging systems, imaging detectors are fixedly coupled to the gantry 256 and in a stationary position, for example, in a PET imaging system (e.g., a ring of imaging detectors). It also should be noted that the imaging detectors 252 and 254 may be formed from different materials as described herein and provided in different configurations known in the art.

One or more collimators may be provided in front of the radiation detection face (not shown) of one or more of the imaging detectors 252 and 254. The imaging detectors 252 and 252 acquire a 2D image that may be defined by the x and y location of a pixel and the location of the imaging detectors 252 and 254. The radiation detection face (not shown) is directed towards, for example, the patient 258, which may be a human patient or animal. It should be noted that the gantry 256 may be configured in different shapes, for example, as a “C”.

A controller unit 264 may control the movement and positioning of the patient table 262 with respect to the imaging detectors 252 and 254 and the movement and positioning of the imaging detectors 252 and 254 with respect to the patient 258 to position the desired anatomy of the patient 258 within the fields of view (FOVs) of the imaging detectors 252 and 254, which may be performed prior to acquiring an image of the anatomy of interest. The controller unit 264 may have a table controller 265 and a gantry motor controller 266 that each may be automatically commanded by a processing unit 268, manually controlled by an operator, or a combination thereof. The table controller 265 may move the patient table 258 to position the patient 258 relative to the FOV of the imaging detectors 252 and 254. Additionally, or optionally, the imaging detectors 252 and 254 may be moved, positioned or oriented relative to the patient 258 or rotated about the patient 258 under the control of the gantry motor controller 266.

The imaging data may be combined and reconstructed into an image as described herein, which may comprise two-dimensional (2D) images, a three-dimensional (3D) volume or a 3D volume over time (4D).

A Data Acquisition System (DAS) 270 receives analog and/or digital electrical signal data produced by the imaging detectors 252 and 254 and decodes the data for subsequent processing as described in more detail herein. An image reconstruction processor 272 receives the data from the DAS 270 and reconstructs an image using any reconstruction process known in the art. A data storage device 274 may be provided to store data from the DAS 270 or reconstructed image data. An input device 276 also may be provided to receive user inputs and a display 278 may be provided to display reconstructed images.

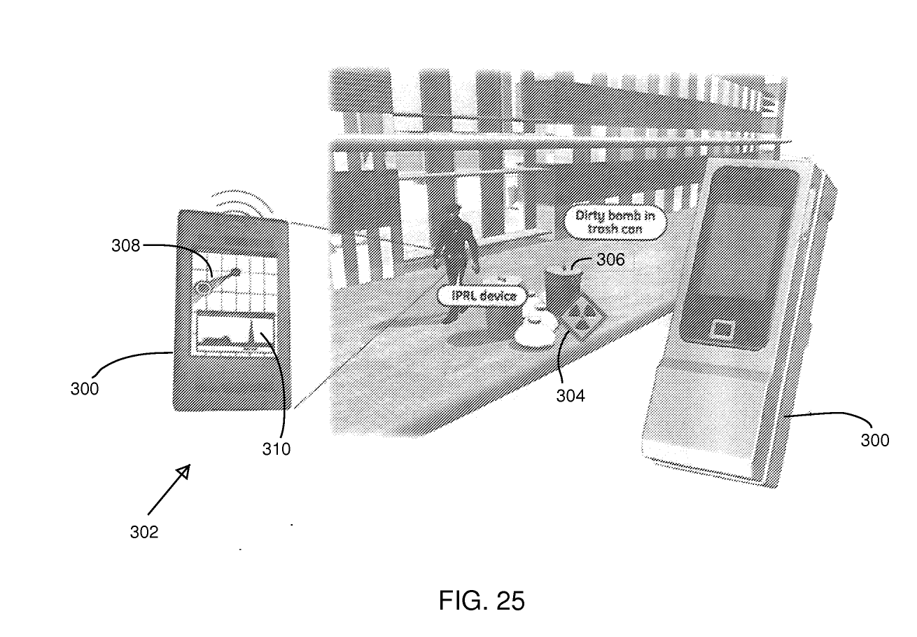

The various embodiments also may be implemented, for example, as part of different types of high energy resolution, radiation spectrometers. FIG. 25 illustrates a handheld spectrometer device 300 (e.g., a RIID) for measuring energy spectra and identifying the radio-isotope type using at least one high energy resolution detector formed from sensor tiles in accordance with one or more embodiments as described herein. As shown, the handheld spectrometer device 300 includes a display 302 that displays the location of a radiation source 304, which is illustrated in a trash can 306. The handheld spectrometer device 300 may broadcast an audible alarm or display a visual indication of the detected radiation source 304.

The handheld spectrometer device 300 is configured to identify, for example, radioactive materials from a high resolution energy spectrum, which may be determined using any suitable radiation resolution detection technique. The identification may include displaying on the display an indication 308 of the direction of the source of the radiation and a measured energy level or profile 310 of the radiation.

In various embodiments, the handheld spectrometer device 300 may, for example, collaborate with peer devices to triangulate the location of the sources of the radiation. Other components may be included as part of the handheld spectrometer device 300. For example, optionally a Global Positioning System (GPS) receiver may be included to provide a GPS location and orientation.

The handheld spectrometer device 300 may be used in different applications, for example, for border security, urban protection, coast guard and port security, and/or international protection, among others.

The various embodiments and/or components, for example, the modules, or components and controllers therein, also may be implemented as part of one or more computers or processors. The computer or processor may include a computing device, an input device, a display unit and an interface, for example, for accessing the Internet. The computer or processor may include a microprocessor. The microprocessor may be connected to a communication bus. The computer or processor may also include a memory. The memory may include Random Access Memory (RAM) and Read Only Memory (ROM). The computer or processor further may include a storage device, which may be a hard disk drive or a removable storage drive such as a floppy disk drive, optical disk drive, and the like. The storage device may also be other similar means for loading computer programs or other instructions into the computer or processor.

As used herein, the term “computer” or “module” may include any processor-based or microprocessor-based system including systems using microcontrollers, Reduced Instruction Set Computers (RISC), ASICs, logic circuits, and any other circuit or processor capable of executing the functions described herein. The above examples are exemplary only, and are thus not intended to limit in any way the definition and/or meaning of the term “computer”.

The computer or processor executes a set of instructions that are stored in one or more storage elements, in order to process input data. The storage elements may also store data or other information as desired or needed. The storage element may be in the form of an information source or a physical memory element within a processing machine.

The set of instructions may include various commands that instruct the computer or processor as a processing machine to perform specific operations such as the methods and processes of the various embodiments. The set of instructions may be in the form of a software program, which may form part of a tangible non-transitory computer readable medium or media. The software may be in various forms such as system software or application software. Further, the software may be in the form of a collection of separate programs or modules, a program module within a larger program or a portion of a program module. The software also may include modular programming in the form of object-oriented programming. The processing of input data by the processing machine may be in response to operator commands, or in response to results of previous processing, or in response to a request made by another processing machine.

As used herein, the terms “software” and “firmware” are interchangeable, and include any computer program stored in memory for execution by a computer, including RAM memory, ROM memory, EPROM memory, EEPROM memory, and non-volatile RAM (NVRAM) memory. The above memory types are exemplary only, and are thus not limiting as to the types of memory usable for storage of a computer program.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the various embodiments without departing from their scope. While the dimensions and types of materials described herein are intended to define the parameters of the various embodiments, the embodiments are by no means limiting and are exemplary embodiments. Many other embodiments will be apparent to those of skill in the art upon reviewing the above description. The scope of the various embodiments should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. §112, sixth paragraph, unless and until such claim limitations expressly use the phrase “means for” followed by a statement of function void of further structure.

This written description uses examples to disclose the various embodiments, including the best mode, and also to enable any person skilled in the art to practice the various embodiments, including making and using any devices or systems and performing any incorporated methods. The patentable scope of the various embodiments is defined by the claims, and may include other examples that occur to those skilled in the art. Such other examples are intended to be within the scope of the claims if the examples have structural elements that do not differ from the literal language of the claims, or if the examples include equivalent structural elements with insubstantial differences from the literal languages of the claims.

What is claimed is:

1. A radiation detector module comprising:
a plurality of sensor tiles configured to detect radiation, the plurality of sensor tiles having (i) top and bottom edges defining top and bottom surfaces of the plurality of sensor tiles, (ii) sidewall edges defining sides of the plurality of sensor tiles, and (iii) corners defined by the top and bottom edges and the sidewall edges; and
at least one beveled surface having an oblique angle, wherein the beveled surface includes beveling of at least one of top or bottom edges, the side wall edges, or the corners.

2. The radiation detector module of claim 1, wherein the beveled surface comprises an oblique facet extending along the sidewall edge from the corners between the top and bottom edges.

3. The radiation detector module of claim 2, further comprising a gap between the beveled surface of adjacent sensor tiles, the gap extending from the top and bottom surfaces of the sensor tiles between the beveled surfaces.

4. The radiation detector module of claim 1, wherein the plurality of sensor tiles are configured in an aligned tile arrangement, wherein the walls of the sensor tiles are aligned.

5. The radiation detector module of claim 1, wherein the plurality of sensor tiles are configured in an offset tile arrangement, wherein the walls of at least some of the sensor tiles are offset with respect to the walls of at least some of the other sensor tiles.

6. The radiation detector module of claim 1, wherein the beveled surface comprises a radiused sidewall edge extending from the corners between the top and bottom edges.

7. The radiation detector module of claim 1, wherein the beveled surface comprises (i) an oblique facet extending along the sidewall edge from the corners between the top and bottom edges, (ii) an oblique facet extending along at least one of the top and bottom edges, and (iii) an oblique facet at the corners.

8. The radiation detector module of claim 1, wherein the beveled surface comprises angled sidewalls extending between the top and bottom edges.

9. The radiation detector module of claim 1, wherein the sensor tiles comprise one of a circular, oval or hexagonal cross-section and the beveled surface comprises and oblique facet extending along the top and bottom edges.

10. The radiation detector module of claim 1, further comprising at least one of a guard band or a guard ring extending around the sensor tiles.

11. The radiation detector module of claim 1, wherein the sensor tiles comprise Cadmium Zinc Telluride (CZT) or Cadmium Telluride.

12. The radiation detector module of claim 1, further comprising a detector package having an interconnect arrangement connecting the sensor tiles to a ceramic substrate, wherein the interconnect arrangement comprise an anisotropic conductive material.

13. The radiation detector module of claim 12, wherein the interconnect arrangement comprises a plurality of deformable metal vias or balls within the anisotropic conductive material providing electrical connection between the sensor tiles and processing circuitry.

14. The radiation detector module of claim 13, further comprising control pins configured to adjust a pressure to deform the metal vias and allow disassembly and reassembly of the detector package for serviceability.

15. The radiation detector module of claim 12, wherein the detector package further comprises a foam layer surrounding the sensor tiles.

16. The radiation detector module of claim 12, wherein the detector package further comprises a surface passivation and encapsulation layer surrounding the sensor tiles.

17. A medical imaging system comprising:
a gantry; and
at least one imaging detector formed from a plurality of detectors modules, wherein the detector modules include a plurality of sensor tiles configured to detect radiation, and having at least one beveled surface defining an oblique angle facet, wherein the beveled surface includes at least one of an edge or a corner of the plurality of sensor tiles.

18. The medical imaging system of claim 17, wherein the radiation detector module further comprises a detector package having an interconnect arrangement connecting the sensor tiles to a ceramic substrate, the interconnect arrangement comprising an anisotropic conductive material, and wherein the interconnect arrangement comprises a plurality of deformable metal vias within the anisotropic conductive material providing electrical connection between the sensor tiles and processing circuitry, and control pins configured to adjust a pressure to deform the metal vias.

19. A radiation spectrometer system comprising at least one high energy resolution detector formed from a plurality of detectors modules, wherein the detector modules include a plurality of sensor tiles configured to detect radiation, and having at least one beveled surface defining an oblique angle facet, wherein the beveled surface includes at least one of an edge or a corner of the plurality of sensor tiles.

20. A method for forming a detector module for a radiation detector, the method comprising:
cutting a substrate to form a plurality of sensor tiles;
forming at least one beveled surface defining an oblique angle facet on the sensor tiles, wherein the beveled surface includes at least one of an edge or a corner of the plurality of sensor tiles; and
forming a detector module from the sensor tiles having the at least one beveled surface.

21. The method of claim 20, further comprising packaging the detector module in a detector package having an interconnect arrangement connecting the sensor tiles to a ceramic substrate, the interconnect arrangement comprising an anisotropic conductive material, and wherein the interconnect arrangement comprises a plurality of deformable metal vias within the anisotropic conductive material providing electrical connection between the sensor tiles and processing circuitry, and control pins configured to adjust a pressure to deform the metal vias.
